(19) United States
(12) Patent Application Publication
(10) Pub. No.: US 2024/0218505 A1
(43) Pub. Date: Jul. 4, 2024

(54) METHOD OF FORMING MOLYBDENUM SILICIDE

(71) Applicant: ASM IP Holding B.V., Almere (NL)

(72) Inventors: Jiyeon Kim, Mesa, AZ (US); YoungChol Byun, Tempe, AZ (US); Petri Raisanen, Gilbert, AZ (US); Sang Ho Yu, Cupertino, CA (US); Sukanya Datta, Phoenix, AZ (US); Chiyu Zhu, Helsinki (FI); Jan Willem Maes, Wilrijk (BE); Saima Ali, Helsinki (FI); Elina Färm, Helsinki (NL)

(21) Appl. No.: 18/396,829

(22) Filed: Dec. 27, 2023

Related U.S. Application Data
(60) Provisional application No. 63/477,954, filed on Dec. 30, 2022.

(51) Int. Cl. C23C 16/42; C23C 16/04

(52) U.S. Cl. CPC C23C 16/42; C23C 16/04

(57) ABSTRACT

Methods of forming molybdenum silicide are disclosed. Exemplary methods can include selectively forming molybdenum silicide on a first surface relative to a second surface. Additionally or alternatively, exemplary methods can include a cleaning step prior to forming the molybdenum silicide.

### CROSS-REFERENCE TO RELATED APPLICATIONS

This application is a nonprovisional of, and claims priority to and the benefit of, U.S. Provisional Patent Application No. 63/477,954, filed Dec. 30, 2022 and entitled “METHOD OF FORMING MOLYBDENUM SILICIDE,” which is hereby incorporated by reference herein.

### FIELD

The present disclosure relates to methods and apparatus for the manufacture of electronic devices. More particularly, the disclosure relates to methods for forming molybdenum silicide on a surface of a substrate.

### BACKGROUND

Conductive layers are often formed during the manufacture of electronic devices. For example, device structures that are formed during the manufacture of electronic devices often include conductive layers of tungsten or copper, which can form, for example, conductive plugs or lines within vias or trenches formed within dielectric material. Tungsten and copper can diffuse through most dielectric material. Manufacturing techniques can include use of barrier layers, such as titanium nitride, to mitigate diffusion of tungsten, copper or the like, thereby improving device reliability and device yield. However, the barrier layer commonly exhibits a high electrical resistivity and therefore results in an increase in the overall electrical resistivity of the semiconductor device structure. Furthermore, formation of a barrier layers adds to a complexity of forming structures including conductive layers and generally requires additional equipment. For example, the barrier layer is often formed in one reaction chamber and the conductive layer (e.g., copper or tungsten) is formed in another reaction chamber. Yet further, it can be difficult to form defect-free conductive material within vias, particularly as an aspect ratio of the vias increases and/or as a cross-section dimension of the via openings decreases.

Recently, molybdenum has gained interest as a metal for forming conductive layers during the manufacture of electronic devices. Molybdenum may work well for some applications. However, in some cases, device structures with deposited molybdenum may exhibit an undesirably high contact resistance. Accordingly, improved methods for forming conductive layers suitable for use in the manufacture of electronic devices are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming molybdenum silicide on a surface of a substrate. As set forth in more detail below, methods described herein can be used during the manufacture of electronic devices. Such methods can reduce complexity and/or cost of manufacturing devices, provide conductive layers with reduced contact resistance, provide selective layer deposition techniques, and/or allow for filling vias or other recesses on a substrate surface in a relatively defect-free manner. By way of examples, methods described herein can be used in the formation of memory, logic, other gate-electrode devices, organic light emitting diodes, liquid crystal displays, thin film solar cells, other photovoltaic devices, and the like.

In accordance with examples of the disclosure, a method of selectively forming molybdenum silicide on a surface of a substrate is provided. An exemplary method includes providing a substrate within a reaction chamber, the substrate comprising a first surface and a second surface, the first surface comprising a first material and the second surface comprising a second material different than the first material, and using a cyclical deposition process, selectively depositing a molybdenum silicide layer on the first surface relative to the second surface. Use of a selective molybdenum silicide deposition can allow for a reduced complexity of manufacture of structure including molybdenum silicide and/or can facilitate relatively low contact resistance of material comprising the molybdenum silicide and an overlying layer of molybdenum. In accordance with examples of the disclosure, the cyclical deposition process includes one or more deposition cycles, wherein each deposition cycle includes providing an oxygen-free molybdenum precursor to form an absorbed molybdenum species on the first surface; and providing a silicon precursor to react with the molybdenum species to form the molybdenum silicide on the first surface. In accordance with examples of the disclosure, the method can further include a step of depositing a molybdenum layer overlying the molybdenum silicide layer. In such cases, the method can additionally include forming a capping layer overlying the molybdenum silicide layer. Additionally or alternatively, the method can include a step of cleaning a surface of the substrate before the step of selectively depositing a molybdenum silicide layer.

In accordance with additional examples of the disclosure, another method of forming molybdenum silicide on a surface of a substrate is provided. The method includes cleaning a surface of a substrate prior to forming the molybdenum silicide. The cleaning can include using activated species formed using a fluorine-containing gas and activated species formed using a hydrogen-containing or NH₃-containing gas to form a cleaned surface. The molybdenum silicide can be formed as described above. Alternatively, the molybdenum silicide can be formed using an oxygen-free molybdenum precursor to deposit a layer of molybdenum on the cleaned surface, and heating the substrate to a temperature of about 550° C. to about 800° C. or about 500° C. to about 750° C. to form the molybdenum silicide. The activated species formed using a fluorine-containing gas and/or the activated species formed using a hydrogen-containing or NH₃-containing gas can be formed using a remote plasma apparatus. The step of depositing the layer of molybdenum can be a cyclical deposition process that includes providing the oxygen-free molybdenum precursor to the reaction chamber, and providing a reactant to the reaction chamber. The step of heating can include rapid thermal processing.

These and other embodiments will become readily apparent to those skilled in the art from the following detailed description of certain embodiments having reference to the attached figures. The invention is not limited to any particular embodiments disclosed.

### BRIEF DESCRIPTION OF DRAWINGS

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIGS. 2-5 illustrate structures in accordance with examples of the disclosure.

FIG. 6 illustrates another method in accordance with exemplary embodiments of the disclosure.

FIGS. 7-10 illustrate additional structures in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and structures provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As set forth in more detail below, various embodiments of the disclosure provide methods for forming molybdenum silicide on a surface. Exemplary methods can be used to selectively form molybdenum silicide on one surface of a substrate relative to another surface. Additionally or alternatively, exemplary methods can be used to form molybdenum silicide on a relatively clean (e.g., having a (e.g., native) oxide removed) surface. Methods described herein can be used to form molybdenum silicide to reduce contact resistance of a layer comprising molybdenum. Additionally or alternatively, methods can be employed to form molybdenum silicide using a relatively simple process and/or with reduced equipment requirements. Further, in at least some cases, the molybdenum silicide can be formed at a relatively low temperature.

Molybdenum silicide formed in accordance with a method described herein may be particularly well suited for back end of line and middle end of line processing of electronic devices, such as semiconductor devices. By way of particular examples, methods described herein can be used during the formation of logic devices and memory devices, such as dynamic random access memory (DRAM) devices.

In this disclosure, gas can include material that is a gas at normal temperature and pressure (NTP), a vaporized solid and/or a vaporized liquid, and can be constituted by a single gas or a mixture of gases, depending on the context.

The terms precursor and reactant can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. In some cases, the term reactant can be used interchangeably with the term precursor.

As used herein, a molybdenum precursor includes a gas or a material that can become gaseous and that can be represented by a chemical formula that includes molybdenum. An oxygen-free molybdenum precursor includes a molybdenum compound that does not include oxygen in its chemical formula.

As used herein, a silicon precursor includes a gas or a material that can become gaseous and that can be represented by a chemical formula that includes silicon.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group Ill-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material or high k dielectric material is material having a dielectric constant greater than the dielectric constant of silicon dioxide.

As used herein, a structure can be or include a substrate as described herein. Structures can include a substrate and one or more layers overlying the substrate, such as one or more layers formed by a method according to the current disclosure. The structure may include or be used in the formation of, for example, a via or a line in BEOL processing, or a contact or a local interconnect in MEOL processing. The structure may also be used to form a layer in a gate electrode, a buried power rail in logic applications, as well as a word line or a bit line in an advanced memory application.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised of a plurality of semiconductor devices.

The term cyclic deposition process or cyclical deposition process can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. In some cases, a cyclical deposition process can include continually flowing one or more precursors, reactants, or inert gases, and pulsing other of the precursors or reactants.

As used herein, the term purge can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. Further, in this disclosure, the terms including, constituted by and having refer independently to typically or broadly comprising, comprising, consisting essentially of, or consisting of in some embodiments.

In this disclosure, any defined meanings do not necessarily exclude ordinary and customary meanings, in some embodiments.

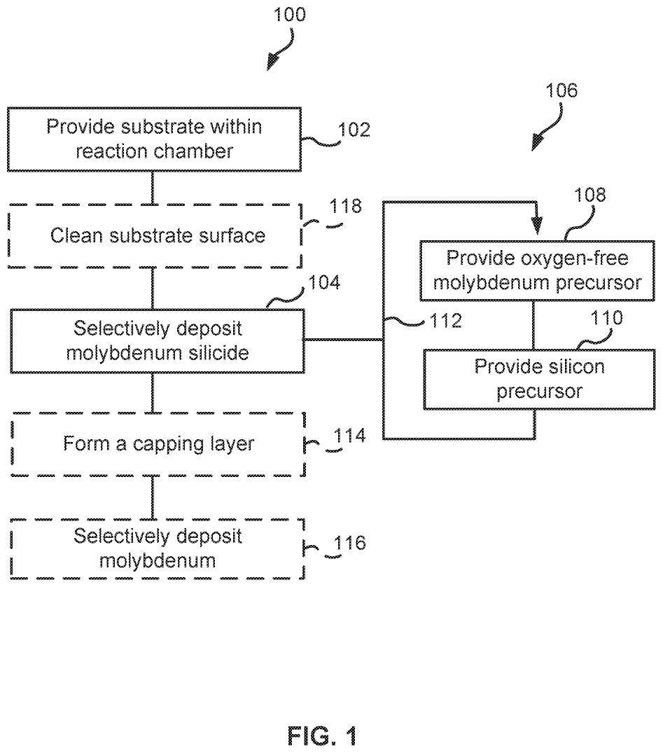

Turning now to the figures, FIG. 1 illustrates a method 100. Method 100 includes the steps of providing a substrate within a reaction chamber (step 102), selectively depositing a molybdenum silicide layer (step 104), optionally forming a capping layer (step 114), and optionally selectively depositing molybdenum (step 116). Further, method 100 can optionally include a step of cleaning a substrate surface (step 118).

During step 102, a substrate is provided within a reaction chamber. The reaction chamber used during step 102 can be or include a reaction chamber of a chemical vapor deposition reactor system configured to perform a cyclical deposition process. The reaction chamber can be a standalone reaction chamber or part of a cluster tool. The reaction chamber can include a substrate heater to heat a substrate to a temperature noted herein. Additionally or alternatively, the reaction chamber can include rapid thermal processing apparatus, such as lamps, to heat the substrate.

The substrate provided during step 102 can include a first surface and a second surface. The first surface can include a first material and the second surface can include a second material different than the first material. For example, the first material can be or include silicon, silicon germanium, doped silicon, doped silicon germanium, or a (e.g., native) oxide thereof. The second material can include, for example, a dielectric material, such as oxides, nitrides, or the like. By way of example, the second material can be or include an interlayer dielectric, such as silicon oxide, silicon nitride, silicon carbonitride, silicon oxycarbide, or the like.

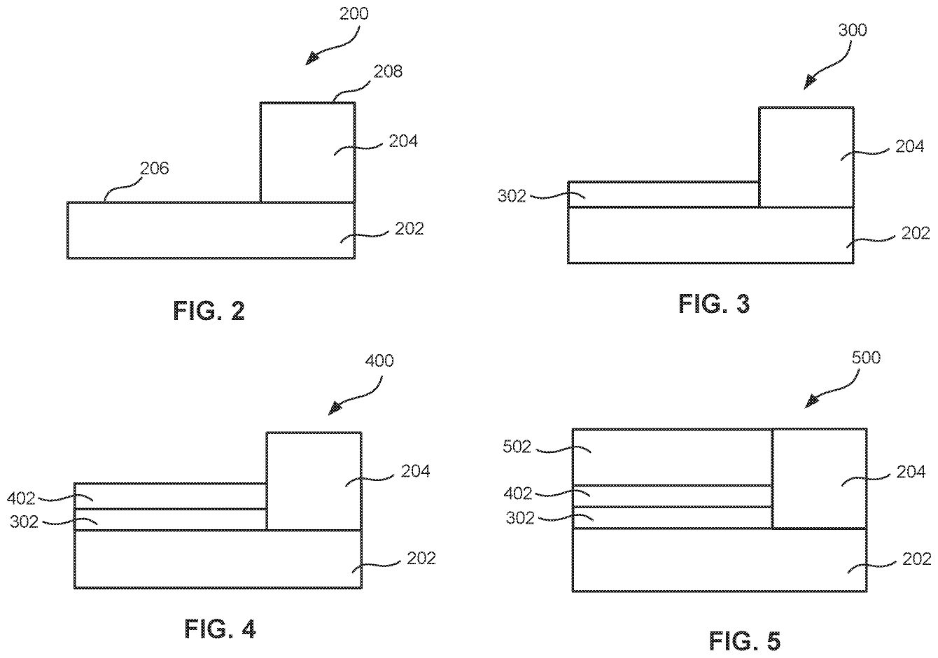

FIG. 2 illustrates a substrate or structure 200 suitable for use as a substrate provided during step 102. Substrate 200 includes a first surface 206 on a first material 202 and a second surface 208 on a second material 204. First material 202 and second material 204 can be as described above. First surface 206 can be or include the first material or a (e.g., native) oxide thereon. As illustrated in FIG. 2, no liner or barrier layer may be present, such that the molybdenum silicide and subsequently formed molybdenum layer can be in direct contact with second material 204, as well as first material 202. This allows for obtaining a low contact resistance and/or relatively less complex manufacturing, compared to typical processing that require a barrier layer between a metal and, for example, an interlayer dielectric layer.

Step 102 can include heating the substrate to a desired deposition temperature within the reaction chamber. In some embodiments of the disclosure, step 102 includes heating the substrate to a temperature of less than 650° C. For example, in some embodiments of the disclosure, heating the substrate to a deposition temperature may comprise heating the substrate (e.g., using a substrate heater) to a temperature between about 200° C. and about 500° C., about 250° C. and about 400° C., about 20° C. and about 1000° C., about 500° C. and about 650° C., or about 500° C. and about 600° C.

In addition to controlling the temperature of the substrate, a pressure within the reaction chamber may also be regulated. For example, in some embodiments of the disclosure, the pressure within the reaction chamber during step 102 may be less than 760 Torr or between 0.2 Torr and 760 Torr, about 1 Torr and 100 Torr, or about 1 Torr and 10 Torr.

During step 104, a molybdenum silicide layer is selectively deposited onto a first surface (e.g., first surface 206) relative to a second surface (e.g., second surface 208). By depositing molybdenum silicide on the first surface, the silicide can be formed without consuming first material 202.

In accordance with examples of the disclosure, and referring to FIG. 1, the step of selectively depositing a molybdenum silicide layer 104 comprises a cyclical deposition process 106 that includes providing an oxygen-free molybdenum precursor to form an absorbed molybdenum species on the first surface (step 108) and providing a silicon precursor to react with the molybdenum species to form the molybdenum silicide on the first surface (step 110). Steps 108 and 110 can be repeated as illustrated by loop 112. Further, steps 108 and 110 can be initiated and/or terminated in any order. Yet further, cyclical deposition process 106 can include one or more (e.g., 1-10 or 1-5) steps 108 and/or 110 prior to proceeding to the other of step 108 or 110.

During step 108, an oxygen-free molybdenum precursor is provided to the reaction chamber. The temperature and pressure within the reaction chamber can be as described above in connection with step 102.

In some embodiments, the oxygen-free molybdenum precursor is provided as a single compound or as mixture of two or more compounds. In a mixture, the other compound(s) in addition to the oxygen-free molybdenum compound may be one or more inert compounds or elements—i.e., inert gases. In some embodiments, the oxygen-free molybdenum precursor is provided in a composition. Compositions suitable for use as composition can include a molybdenum compound and an effective amount of one or more stabilizing agents and/or inert or carrier gases, such as argon, nitrogen, and/or hydrogen. Composition may be a solution or a gas at NTP.

In accordance with examples of the disclosure, the oxygen-free molybdenum compound comprises a molybdenum atom and an organic (e.g., hydrocarbon) ligand. In some embodiments, the molybdenum precursor comprises a metal-organic compound comprising molybdenum. In such cases, the molybdenum precursor can be referred to as a metal-organic molybdenum precursor. An oxygen-free metal-organic molybdenum precursor is herein meant to include a molybdenum compound comprising a molybdenum atom and a hydrocarbon ligand, wherein the molybdenum atom is not directly bonded to a carbon atom. In some embodiments, the oxygen-free metal-organic molybdenum precursor comprises one molybdenum atom, which is not directly bonded with a carbon atom. In some embodiments, the oxygen-free metal-organic molybdenum precursor comprises two or more molybdenum atoms, none of which is directly bonded to a carbon atom. In some embodiments, the oxygen-free metal-organic molybdenum precursor comprises two or more metal atoms, wherein at least one metal atom is not directly bonded to a carbon atom.

In some embodiments, the oxygen-free molybdenum precursor comprises an oxygen-free organometallic molybdenum compound comprising molybdenum. An oxygen-free organometallic molybdenum precursor is herein meant to refer to a molybdenum compound comprising a molybdenum atom and an organic (e.g., hydrocarbon) ligand, wherein the molybdenum atom is directly bonded to a carbon atom. In embodiments in which an oxygen-free molybdenum organometallic precursor comprises two or more metal atoms, one or more (e.g., all) of the metal atoms can be directly bonded with a carbon atom. In some embodiments, oxygen-free molybdenum organometallic precursor comprise only molybdenum, carbon and hydrogen. In other words, oxygen-free molybdenum organometallic precursor does not contain oxygen, nitrogen or other additional elements. In some embodiments, the oxygen-free molybdenum organometallic precursor comprises at least two hydrocarbon ligands. In some embodiments, the oxygen-free molybdenum organometallic precursor comprises at least three hydrocarbon ligands. In some embodiments, the oxygen-free molybdenum organometallic precursor comprises four hydrocarbon ligands. In some embodiments, the oxygen-free molybdenum organometallic precursor comprises a hydrocarbon ligand and a hydride ligand. In some embodiments, the oxygen-free molybdenum organometallic precursor comprises a hydrocarbon ligand and two or more hydride ligands. In some embodiments, the oxygen-free molybdenum organometallic precursor comprises two hydrocarbon ligands and two hydride ligands. Hydrocarbon ligands as described herein can be or include, for example, C1-C10 hydrocarbons.

In some embodiments, the oxygen-free molybdenum precursor comprises one or more cyclic portions. For example, the oxygen-free molybdenum precursor may comprise one or more benzene rings. In some embodiments, the oxygen-free molybdenum precursor comprises two benzene rings. One or both benzene rings may comprise (e.g., C1-C6) hydrocarbon substituents. In some embodiments, each benzene ring of the oxygen-free molybdenum precursor comprises an alkyl substituent. An alkyl substituent may be a methyl group, an ethyl group, or a linear or branched alkyl group comprising three, four, five or six carbon atoms. For example, the alkyl substituent of the benzene ring may be an n-propyl group or an iso-propyl group. Further, the alkyl substituent may be an n-, iso-, tert- or sec-form of a butyl, pentyl or hexyl moiety. In some embodiments, the molybdenum precursor comprises, consists essentially of, or consists of bis(ethylbenzene)molybdenum.

In some embodiments, the oxygen-free molybdenum precursor comprises a cyclopentadienyl (Cp) ligand. For example, the oxygen-free molybdenum precursor may comprise, consist essentially of, or consist of MoCp₂Cl₂ or MoCp₂H₂, Mo(iPrCp)₂Cl₂, Mo(iPrCp)₂H₂, Mo(EtCp)₂H₂.

In some embodiments, the oxygen-free molybdenum precursor comprises a halogenated molybdenum compound comprising or consisting of molybdenum and one or more halogen atoms. The oxygen-free molybdenum precursor can include one or more ligands noted above and one or more halogen atoms. Alternatively, the oxygen-free molybdenum precursor compound can consist of molybdenum and one or more halogen atoms. In some embodiments, the oxygen-free molybdenum precursor comprises a molybdenum chloride compound, a molybdenum iodide compound, or a molybdenum bromide compound. As non-limiting examples, the molybdenum halide precursor may comprise at least one of: molybdenum pentachloride (MoCl₅), molybdenum hexachloride (MoCl₆), molybdenum hexafluoride (MoF₆), molybdenum triiodide (MoI₃), or molybdenum dibromide (MoBr₂). In some embodiments, the molybdenum halide precursor may comprise a molybdenum chalcogenide, and in particular embodiments, the molybdenum halide precursor may comprise a molybdenum chalcogenide halide that does not include oxygen. Exemplary chalcogenides include sulfur, selenium, and tellurium.

A duration of step 108 during each cycle 112 can be between about 0.1 seconds and about 60 seconds, between about 0.1 seconds and about 10 seconds, or between about 0.5 seconds and about 5.0 seconds. A flowrate of the molybdenum precursor to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to about 500 sccm.

During step 110, a silicon precursor is provided to the reaction chamber. In some cases, the silicon precursor comprises a compound having a general formula RₐSiX_{b} or R_{c}X_{d}Si—SiR_{c}X_{d}, where each X can be independently selected from H, a halogen, or other ligand, wherein each R can be a C1-C12 organic group, and where a is 0, 1, 2 or 3, b is 4-a, c is 0, 1 or 2, and d is 3-c. R may be a hydrocarbon. If a is two or three, or c is two, each R can be selected independently. In some embodiments, each R is selected from alkyls and aryls. For clarity, X may represent different (e.g., independently selected) ligands. Thus, in some embodiments, an auxiliary reactant may be, for example, SiH₂Br₂, SiH₂I₂ or SiH₂Cl₂.

In some embodiments, X is a hydrogen, a substituted or an unsubstituted alkyl or aryl or a halogen. In some embodiments, X is H. In some embodiments, X is an alkyl or an aryl. In some embodiments, X is a C1 to C4 alkyl. In some embodiments, X is a substituted alkyl or aryl. In some embodiments, X is a substituted alkyl or aryl, wherein the substituent comprises silicon. In some embodiments, X is selected from a group consisting of H, Me, Et, nPr, iPr, nBu, tBu, M′Me₃, M′Et₃, M′Pr₃, M′Bu₃, Cl, Br, or I, wherein M′ is Si.

In some embodiments, the silicon precursor may have a formula R₃Six, R₂SiX₂, R_{S}iX₃, or SiX₄, where a, b, R and X are as above. In some embodiments, a silicon atom does not comprise four identical substituents. In some embodiments, the silicon precursor is not SiH₄. In some embodiments, the silicon precursor is not SiH₂Me₂. In some embodiments, the silicon precursor is not SiH₂Et₂. In some embodiments, the silicon precursor is not Si₂H₂.

In some cases, exemplary silicon precursors suitable for use with step 110 can consist of silicon and hydrogen. For example, the silicon precursor may comprise a silane, such as, for example, silane (SiH₄), disilane (Si₂H₆), trisilane (Si₃H₈), tetrasilane (Si₄H₁₀) or higher order silanes with the general empirical formula SiₓH₍₂ₓ₊₂₎.

In some cases, the silicon precursor can include an amino silane, such as one or more of silanediamine N,N,N′,N-tetraethyl (C₈H₂₂N₂Si), BTBAS (bis(tertiarybutylamino)silane), BDEAS (bis(diethylamino)silane), or TDMAS (tris(dimethylamino)silane), hexakis(ethylamino)disilane (Si₂(NHC₂H₅)₆.

In accordance with further examples of the disclosure, the silicon precursor does not include a compound comprising oxygen. In some cases, step 110 of providing a silicon precursor includes providing another gas, such as a hydrogen-containing gas (e.g., H₂, NH₃, or the like).

A duration of step 110 during each cycle 112 can be between about 0.1 seconds and about 60 seconds, between about 0.1 seconds and about 10 seconds, or between about 0.5 seconds and about 5.0 seconds. A flowrate of the silicon precursor to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to about 500 sccm.

The oxygen-free molybdenum and/or silicon precursor can be purged from the reaction chamber—e.g., after each pulse and/or upon completion of a step 108, 110 and/or each cycle 112. As noted above, a purge can be effected either in time or in space, or both. Purging times can be, for example, from about 0.01 seconds to about 20 seconds, from about 0.05 seconds to about 20 seconds, or from about 1 second to about 20 seconds, or from about 0.5 seconds to about 10 seconds, or from about 1 second to about 7 seconds. A flowrate of a purge gas to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to about 500 sccm.

FIG. 3 illustrates a structure 300 after step 104. As illustrated, a molybdenum silicide layer 302 is selectively formed overlying first surface 206, relative to second surface 208. In this context, selectively formed means a greater amount of molybdenum silicide is deposited on first surface 206, relative to second surface 208. In some embodiments of the disclosure, a selectivity of a process can be expressed as a ratio of material deposited (e.g., a layer thickness) on the first surface relative to the amount of material (e.g., a layer thickness) formed on the first and second surfaces combined. For example, if 10 nm of molybdenum silicide is deposited on first surface 206 and 1 nm of molybdenum silicide is deposited on second surface 208, the selective deposition process will be considered to have 91% selectivity. In some embodiments, the selectivity of the methods disclosed herein is greater than 50%, greater than 75%, greater than 80%, greater than 90%, greater than 95%, greater than 97.5%, greater than 98%, greater than 99%, or even about 100%.

Molybdenum silicide layer can comprise, consist essentially of, or consist of molybdenum silicide. A layer consisting of molybdenum silicide may include an acceptable amount of impurities, such as carbon, chlorine or other halogen, and/or hydrogen that may originate from one or more precursors used to deposit the molybdenum silicide layer.

A thickness of molybdenum silicide layer 302 can be, for example, about 1 to about 40 nm or about 2 to about 10 nm. Molybdenum silicide layer can comprise, consist essentially of or consist of molybdenum and silicon. A layer consisting of molybdenum silicide can include an acceptable amount of impurities, such as carbon, chlorine or other halogen, and/or hydrogen that may originate from one or more precursors used to deposit the molybdenum silicide layer.

In some cases, method 100 can include step 114 of forming a capping layer 402. During step 114, a capping layer 402, illustrated in FIG. 4, can be formed (e.g., directly) overlying molybdenum silicide layer 302. Capping layer 402 can be or include, for example, a molybdenum nitride layer.

Capping layer 402 can be formed using a (e.g., selective and/or cyclical) deposition process by providing a molybdenum precursor and a nitrogen reactant to a reaction chamber. The molybdenum precursor can be or include any molybdenum precursor as described herein. The molybdenum precursor flowrate and pulse times can be as described above in connection with step 108.

The nitrogen reactant can be or include, for example, at least one of ammonia (NH₃), hydrazine (N₂H₄), triazane (N₃H₅), an alkyl substituted hydrazine or triazine, such as tertbutylhydrazine (C4H₉N₂H₃), methylhydrazine (CH₃NHNH₂), dimethylhydrazine ((CH₃)₂N₂H₂), or a nitrogen plasma, wherein a nitrogen plasma includes atomic nitrogen, nitrogen radicals and/or excited nitrogen species.

A duration of a step of providing the nitrogen reactant to the reaction chamber can be between about 0.1 seconds and about 60 seconds, between about 0.1 seconds and about 10 seconds, or between about 0.5 seconds and about 5.0 seconds. A flowrate of the nitrogen reactant to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to about 500 sccm.

A thickness of capping layer 402 can be between about 1 and about 20 nm or between about 2 and about 10 nm. Capping layer 402 can include about 10 to about 90% or about 20 to about 70 at % molybdenum and/or about 30 to about 60 at % nitrogen.

During step 116, molybdenum can be selectively deposited (e.g., directly) onto capping layer 402 or molybdenum silicide layer 302.

Step 116 can include a (e.g., cyclical) deposition process that includes providing a molybdenum precursor and a reactant to the reaction chamber. In the method according to the current disclosure, the reactant may be contacted with the substrate comprising a chemisorbed molybdenum precursor. The conversion of a molybdenum precursor to molybdenum may take place at the substrate surface. In some embodiments, the conversion may take place at least partially in the gas phase.

The molybdenum precursor, the molybdenum precursor flowrate, and the molybdenum precursor duration during step 116 can be as described above in connection with step 104. Similarly, the temperatures and pressures within a reaction chamber can be as described above in connection with step 104.

Exemplary reactants suitable for use with step 116 include reducing agents. Exemplary reducing agents include one or more of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), a hydrogen plasma, hydrogen radicals, hydrogen excited species, (e.g., C1-C4) alcohols, (e.g., C1-C4) aldehydes, (e.g., C1-C4) carboxylic acids, (e.g., B1-B12) boranes, or an amine. By way of particular examples, the first reactant can be or include at least one of hydrogen (H₂), silane (SiH₄), disilane (Si₂H₆), trisilane (Si₃H₈), germane (GeH₄), digermane (Ge₂H₆), borane (BH₃), or diborane (B₂H₆).

A flowrate of the reactant to the reaction chamber can be greater than zero and less than 30 slm, or less than 15 slm, or less than 10 slm, or less than 5 slm, or less than 1 slm, or even less than 0.1 slm. For example, the flowrate can be between about 0.1 to 30 slm, from about 5 to 15 slm, or equal to or greater than 10 slm. In the case of cyclical deposition processes, the reactant can be pulsed—e.g., for a duration between about 0.01 seconds and about 180 seconds, between about 0.05 seconds and about 60 seconds, or between about 0.1 seconds and about 30 seconds. In some embodiments, molybdenum precursor may be pulsed more than one time, for example two, three or four times, before a reactant is pulsed to the reaction chamber. Similarly, there may be more than one pulse, such as two, three or four pulses, of a reactant before molybdenum precursor is pulsed (i.e., provided) to the reaction chamber.

In some cases, a purge can be employed to remove any excess reactant and/or reaction byproducts from a reaction chamber—e.g., after a reactant pulse and/or at a completion of a deposition step. The purge can be as described above.

As illustrated in FIGS. 1 and 5, during step 116 of selectively depositing a molybdenum, a layer of molybdenum 502 is selectively formed overlying molybdenum silicide layer 302 and/or capping layer 402 to form structure 500. Step 116 can be performed within the same reaction chamber as step 104 and/or 114.

The molybdenum (e.g., molybdenum layer 502) may be at least partly in elemental form. Thus, the oxidation state of molybdenum may be zero. Thus, molybdenum layer 502 may comprise, consist essentially of, or consist of molybdenum.

In some embodiments, a molybdenum layer (e.g., molybdenum layer 502) comprises, for example, about 60 to about 99 atomic percentage (at. %) molybdenum, or about 75 to about 99 at. % molybdenum, or about 75 to about 95 at. % molybdenum, or about 80 to about 95 at. % molybdenum. A molybdenum layer deposited by a method according to the current disclosure may comprise, for example about 80 at. %, about 83 at. %, about 85 at. %, about 87 at. %, about 90 at. %, about 95 at. %, about 97 at. % or about 99 at. % molybdenum. A layer consisting of molybdenum may include an acceptable amount of impurities, such as carbon, chlorine or other halogen, and/or hydrogen that may originate from one or more precursors used to deposit the molybdenum layer.

In some embodiments, the molybdenum layer may comprise less than about 20 at. %, less than about 15 at. %, less than about 10 at. %, less than about 8 at. %, less than about 6 at. %, less than about 5 at. %, less than about 4.5 at. %, or less than about 3 at. % carbon.

A thickness of layer of molybdenum 502 can range from about 1 to about 40 nm or about 2 to about 10 nm

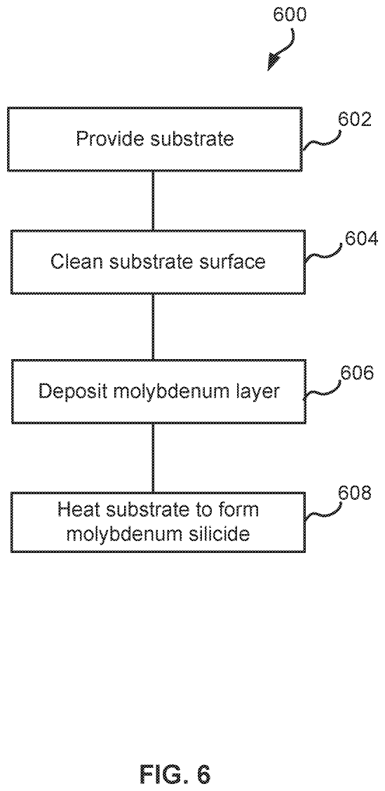

As noted above, method 100 can also include step 118 of cleaning a surface of the substrate before the step of selectively depositing a molybdenum silicide layer. Step 118 can be performed within the reaction chamber or within another reaction chamber—e.g., within the same system module. Cleaning step 118 can be used to remove a (e.g., native) oxide from a surface—e.g., from surface 206. An exemplary cleaning step suitable for step 118 is described in more detail below in connection with FIG. 6.

Turning now to FIG. 6, another method 600 of forming molybdenum silicide on a surface of a substrate is illustrated. Method 600 includes the steps of providing a substrate comprising a surface within a reaction chamber (step 602), cleaning the surface (step 604), depositing a layer of molybdenum on the cleaned surface (step 606), and heating the substrate to form the molybdenum silicide.

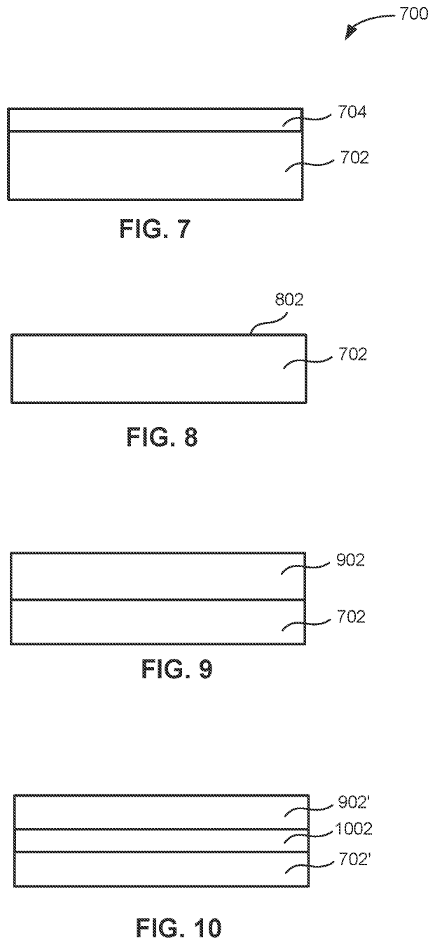

Step 602 of providing a substrate comprising a surface within a reaction chamber can be the same or similar as step 102 described above. An exemplary substrate 700, which includes material 702 and a (e.g., native) oxide 704 is illustrated in FIG. 7. Material 702 can be or include first material 202, as described above. Although not separately illustrated, substrate 700 can include a second material and a second surface, as described above.

During step 604, activated species formed using a fluorine-containing gas and activated species formed using a hydrogen-containing or NH₃-containing gas are formed within or provided to the reaction chamber to form a cleaned surface 802, as illustrated in FIG. 8. Surfaces cleaned in accordance with examples described herein produce higher quality (e.g., less oxygen at an interface) molybdenum silicides, compared to molybdenum silicides formed using, for example, HF as an etchant.

In accordance with examples of the disclosure, activated species formed using a fluorine-containing gas and activated species formed using a hydrogen-containing or NH₃-containing gas to form a cleaned surface are formed using an indirect or remote plasma apparatus. A power used to form a plasma can be about 10 to about 1000 W or about 20 to about 200 W for a 300 mm diameter substrate. A duration of a plasma on-time can be about 1 to about 60 or about 2 to about 10 seconds.

The fluorine-containing gas can be or include, for example, one or more of NF₃, XeF₃, F₂, or the like. A flowrate of the fluorine-containing gas to the remote or indirect plasma apparatus can be about 1 to about 1000 or about 2 to about 100 sccm.

The hydrogen-containing gas can be or include one or more of NH₃, N₂/H₂ (e.g., 10-90 vol. % H₂), hydrazine, a substituted hydrazine and/or triazine as described herein, or the like. A flowrate of the hydrogen-containing gas to the remote or indirect plasma apparatus can be about 1 to about 1000 or about 10 to about 200 sccm.

The fluorine-containing gas and the hydrogen-containing or NH₃-containing gas can be supplied to a plasma apparatus sequentially and/or to separate plasma apparatus or to different regions of a plasma apparatus. The plasma apparatus can include one or more dedicated regions or units, which can be dedicated to forming respective active species. Alternatively, the activated species formed using a fluorine-containing gas and activated species formed using a hydrogen-containing gas can be formed using the same plasma unit or region.

During step 606, a layer of molybdenum 902 is deposited on cleaned surface 802; as illustrated in FIG. 9. Step 606 can be the same or similar as step 116 of method 100, except step 606 need not be, but can be selective, and need not be, but can be cyclical. In particular, step 606 can include using any of the oxygen-free molybdenum precursors and reactants noted above in connection with step 114 and/or 116. Step 606 can be a continuous (e.g., CVD process) or can be a cyclical process as described above in connection with step 116 of method 100. Use of step 604 prior to deposition of the deposition of molybdenum was found to influence whether quality molybdenum silicide formed—or not during step 608.

A thickness of layer of molybdenum 902 can range from about 1 to about 100 or about 2 to about 20 nm.

During step 608, the substrate can be heated to a temperature of about 550° C. to about 700° C. or about 400 to about 900° C. to form molybdenum silicide 1002, illustrated in FIG. 10. During step 608, a portion of material 702 can be consumed to form material 702′ and a portion of layer of molybdenum 902 can be consumed to form layer of molybdenum 902′.

A thickness of molybdenum silicide 1002 can be about 1 to about 40 nm or about 2 to about 10 nm. A composition of molybdenum silicide 1002 can include between about 20 to about 80 or about 33 to about 75 at % molybdenum and/or between about 0.1 to about 10 or less than about 20 at % oxygen.

Heating the substrate, step 608, can include heating the substrate using rapid thermal processing. The rapid thermal processing can be performed using one or more lamps and can be performed within the reaction chamber or within another reaction chamber—e.g., within the same process module as the reaction chamber.

In some embodiments, a method according to the current disclosure comprises a thermal deposition process. In thermal deposition, the chemical reactions are promoted by increased temperature relevant to ambient temperature. Generally, temperature increase provides the energy for the formation of molybdenum silicide, a capping layer, and/or molybdenum in the absence of other external energy sources, such as plasma, radicals, or other forms of radiation. For example, one or more (e.g., all of steps 104, 114, 116, and 606) can be thermal processes. In some embodiments, the cleaning step (e.g., step 118 or step 604) includes forming a plasma to form activated species as described above.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of selectively forming molybdenum silicide on a surface of a substrate, the method comprising:
providing a substrate within a reaction chamber, the substrate comprising a first surface and a second surface, the first surface comprising a first material and the second surface comprising a second material different than the first material;
using a cyclical deposition process, selectively depositing a molybdenum silicide layer on the first surface relative to the second surface, the cyclical deposition process comprising one or more deposition cycles, each deposition cycle comprising:
providing an oxygen-free molybdenum precursor to form an absorbed molybdenum species on the first surface; and
providing a silicon precursor to react with the molybdenum species to form the molybdenum silicide layer on the first surface.

2. The method according to claim 1, wherein the first material comprises silicon.

3. The method according to claim 2, wherein the second material comprises SiO₂ or SiN or SiCN or SiCO.

4. The method according to claim 1, wherein the oxygen-free molybdenum precursor comprises a halogen.

5. The method according to claim 3, wherein the oxygen-free molybdenum precursor consists of molybdenum and one or more halogens.

6. The method according to claim 1, wherein the oxygen-free molybdenum precursor comprises an organic ligand.

7. The method according to claim 1, wherein the silicon precursor has a general formula RₐSiX_{b} or R_{c}X_{d}Si—SiR_{c}X_{d}, where each X can be independently selected from H, a halogen, or other ligand, wherein each R can be a C1-C12 organic group, and where a is 0, 1, 2 or 3, b is 4-a, c is 0, 1 or 2, and d is 3-c.

8. The method according to claim 1, wherein a temperature within the reaction chamber is between about 500° C. and about 600° C. or between 200° C. and 500° C.

9. The method according to claim 1, further comprising providing a hydrogen-containing gas during the step of providing the silicon precursor.

10. The method according to claim 1, further comprising a step of selectively depositing a molybdenum layer overlying the molybdenum silicide layer within the reaction chamber.

11. The method according to claim 1, further comprising a step of forming a capping layer overlying the molybdenum silicide layer.

12. The method according to claim 1, further comprising a step of cleaning a surface of the substrate within the reaction chamber before the step of selectively depositing a molybdenum silicide layer.

13. A method of forming molybdenum silicide on a surface of a substrate, the method comprising:
providing a substrate comprising a surface within a reaction chamber;
cleaning the surface using activated species formed using a fluorine-containing gas and activated species formed using a hydrogen-containing or NH₃-containing gas to form a cleaned surface;
using an oxygen-free molybdenum precursor, depositing a layer of molybdenum on the cleaned surface; and
heating the substrate to a temperature of about 500° C. to about 750° C. to form the molybdenum silicide.

14. The method according to claim 13, wherein the fluorine-containing gas comprises one or more of NF₃, XeF₃, or F₂

15. The method according to claim 13, wherein the hydrogen-containing gas comprises one or more of NH₃ and H₂.

16. The method according to claim 13, wherein the activated species formed using a fluorine-containing gas and the activated species formed using a hydrogen-containing gas are formed using a remote plasma apparatus.

17. The method according to claim 13, wherein the step of depositing the layer of molybdenum comprises a cyclical deposition process comprising:
providing the oxygen-free molybdenum precursor to the reaction chamber; and
providing a reactant to the rection chamber.

18. The method according to claim 17, wherein the oxygen-free molybdenum precursor comprises a halogen.

19. The method according to claim 13, wherein the step of heating comprises rapid thermal processing.

20. A method of forming molybdenum silicide on a surface of a substrate, the method comprising:
providing a substrate comprising a surface within a reaction chamber;
cleaning the surface using activated species formed using a fluorine-containing gas and activated species formed using a hydrogen-containing gas to form a cleaned surface;
forming molybdenum silicide on the cleaned surface; and
using a cyclical deposition process, depositing a layer comprising molybdenum.
